(19) United States
(12) Patent Application Publication
(10) Pub. No.: US 2013/0234181 A1
(43) Pub. Date: Sep. 12, 2013

(54) SEMICONDUCTOR LIGHT-EMITTING DEVICE

(71) Applicant: Gen WATARI, Fukuoka-ken (JP)

(72) Inventor: Gen WATARI, Fukuoka-ken (JP)

(73) Assignee: KABUSHIKI KAISHA TOSHIBA, Tokyo (JP)

(21) Appl. No.: 13/600,117

(22) Filed: Aug. 30, 2012

(30) Foreign Application Priority Data
Mar. 7, 2012 (JP) 2012-050025

(51) Int. Cl. H01L 33/50

(52) U.S. Cl. 257/98; 257/E33.061

(57) ABSTRACT

A semiconductor light-emitting device includes first and second lead frames that are arranged with a separation on a common plane, a semiconductor light-emitting element that is electrically connected to the first and second lead frames, and a resin body that covers the first and second lead frames and the semiconductor light-emitting element, and includes fluorescent materials that absorb light emitted from the semiconductor light-emitting element and emit light with a wavelength longer than the wavelength of the light absorbed. The resin body has a shape that becomes smaller in cross-section with increasing distance from the common plane.

### CROSS-REFERENCE TO RELATED APPLICATION

This application is based upon and claims the benefit of priority from Japanese Patent Application No. 2012-050025, filed Mar. 7, 2012; the entire contents of which are incorporated herein by reference.

### FIELD

Embodiments described herein relate to a semiconductor light-emitting device.

### BACKGROUND

In a package for semiconductor light-emitting devices, a polyamide thermoplastic resin has frequently been used as an envelope that encloses a sealing resin to control the luminous intensity distribution and to raise light extraction from the package.

However, with the polyamide thermoplastic resin, its degradation due to heat and light is larger than that of silicone resins, etc., which are used as sealing resins, and there are issues with reliability over the long term. Accordingly, polyamide thermoplastic resin have not been used as sealing resins for packages.

A semiconductor light-emitting device in which a nitride semiconductor light-emitting element is mounted and bonded to a lead frame is known. A transparent resin body with a rectangular parallelepiped shape containing fluorescent materials is installed on the lead frame of the device and the nitride semiconductor light-emitting element is embedded into this resin body.

With the use of the nitride semiconductor light-emitting element for emitting blue light and the transparent resin body containing fluorescent materials for absorbing the blue light and emitting yellow light, the semiconductor light-emitting device for emitting white light is obtained.

However, in this semiconductor light-emitting device, the ratio of the intensity of the blue light and the intensity of the yellow light depends upon the viewing direction, because of directional scattering of the chromaticity.

Examples of related art include Patent References of JP-A-2009-94351 and JP-A-2009-260234.

### DESCRIPTION OF THE DRAWINGS

FIG. 1 is a cross section showing the semiconductor light-emitting device of an embodiment.

FIG. 2 is a perspective view showing the semiconductor light-emitting device of the embodiment.

FIG. 3 is a cross section showing a semiconductor light-emitting device of a comparative example.

FIG. 4 is a flow chart showing the manufacturing processes of the semiconductor light-emitting device of the embodiment.

FIGS. 5A to 5C are cross sections sequentially showing the main parts of the semiconductor light-emitting device of the embodiment.

FIGS. 6A and 6B are cross sections showing the main parts of another semiconductor light-emitting device of the embodiment.

FIG. 7 is a cross section showing another semiconductor light-emitting device of the embodiment.

FIG. 8 is a perspective view showing another semiconductor light-emitting device of the embodiment.

FIGS. 9A and 9B are cross sections showing the main parts of the manufacturing processes of another semiconductor light-emitting device of the embodiment.

FIG. 10 is a cross section showing another semiconductor light-emitting device of the embodiment.

FIG. 11 is a perspective view showing another semiconductor light-emitting device of the embodiment.

FIG. 12 is a cross section showing the main parts of the manufacturing processes of another semiconductor light-emitting device of the embodiment.

### DETAILED DESCRIPTION

In general, according to one embodiment, an explanation given will be given with reference to the FIGS.

According to an embodiment, there is provided a semiconductor light-emitting device capable of operating with little scattering of the chromaticity due to direction.

According to an embodiment, in a semiconductor light-emitting device, first and second lead frames are arranged with a separation on the same plane. A semiconductor light-emitting element has first and second terminals. The first terminal is electrically connected to the first lead frame, and the second terminal is electrically connected to the second lead frame. A resin body is installed to cover the first and second lead frames so that the semiconductor light-emitting element is embedded in the resin body. In the resin body, the size of the upper side opposite to the first and second lead frames is smaller than the size of the lower side at the first and second lead frames. The resin body includes fluorescent materials that absorb light, which is emitted from the semiconductor light-emitting element. These fluorescent materials emit light with a wavelength longer than the wavelength of the light that they absorb.

### Embodiment

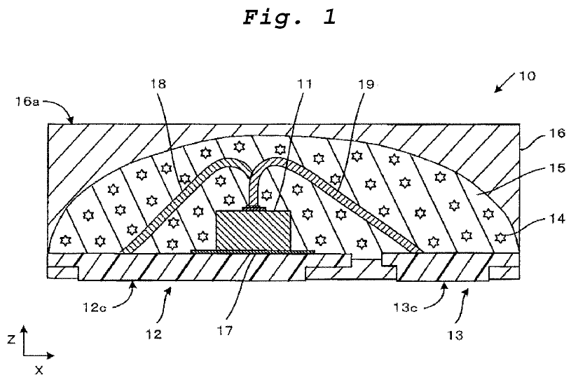

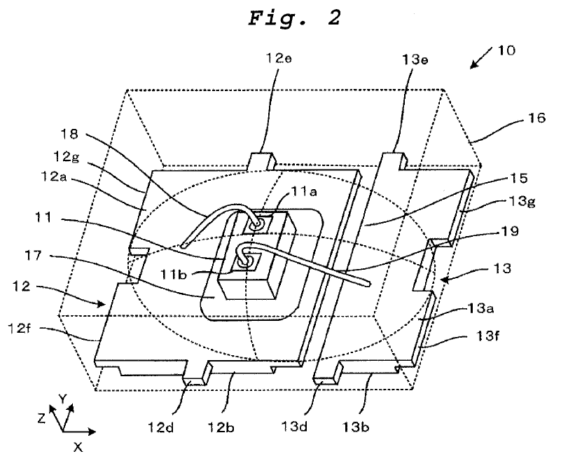

The semiconductor light-emitting device of this embodiment will be explained with reference to FIGS. 1 and 2. FIG. 1 is a cross sectional diagram showing the semiconductor light-emitting device of this embodiment. FIG. 2 is a perspective diagram showing the semiconductor light-emitting device of this embodiment.

The semiconductor light-emitting device of this embodiment is a semiconductor light-emitting device in which a nitride semiconductor light-emitting element which emits blue light is embedded in a transparent resin containing fluorescent materials that absorb blue light and emit yellow light.

As shown in FIGS. 1 and 2, a semiconductor light-emitting device 10 of this embodiment includes a semiconductor light-emitting element 11 that is electrically connected to first and second lead frames 12 and 13. A dome-shaped resin body 15 containing fluorescent materials 14 is installed so that the semiconductor light-emitting element 11 is covered thereby. In addition, a transparent resin body 16 with a rectangular parallelepiped shape is installed so that the resin body 15 is covered thereby.

The semiconductor light-emitting element 11 is a nitride semiconductor light-emitting element that emits blue light with a wavelength of about 450 nm, for instance. In the semiconductor light-emitting element 11, an N-type GaN clad layer, a semiconductor luminous layer having a multiple quantum well structure in which InGaN well layers and GaN barrier layers are laminated in an alternating manner, a P-type GaN clad layer, and a P-type GaN contact layer are sequentially laminated on a sapphire substrate.

Referring now to FIG. 2, a first terminal (P side electrode) 11a is installed on the P-type GaN contact layer. A second terminal (N side electrode) 11b is installed in a notch (not shown in the FIG.) for exposing the N-type GaN clad layer.

The first and second lead frames 12 and 13 have a tabular shape. The first and second lead frames 12 and 13 are on the same plane and are arranged with a separation in the X direction of the paper.

In the first lead frame 12, one base part 12a with a rectangular shape from the view in the Z-axis direction is installed; four suspension pins 12d, 12e, 12f, and 12g extend from the base part 12a. In the second lead frame 13, one base part 13a with a rectangular shape from the view in the Z-axis direction is installed; four suspension pins 13d, 13e, 13f, and 13g extend from the base part 13a. Compared with the first lead frame 12, the length of the second lead frame 13 in the X direction is short and the length in the Y direction is the same.

At position 12b, which is located at the central part in the X direction of the base part 12a on the lower surface 12c of the first lead frame 12, a convex part is formed. At position 13b, which is located at the central part in the X direction of the base part 13a on the lower surface 13c of the second lead frame 13, a convex part is formed.

On the base part 12a of the first lead frame 12, the semiconductor light-emitting element 11 is mounted using a die mount medium 17 such as an adhesive. The first terminal 11a of the light emitting-element 11 is electrically connected to the base part 12a of the first lead frame 12 via a wire 18. The second terminal 11b is electrically connected to the base part 13a of the second lead frame 13 via a wire 19.

The fluorescent materials 14 may be, for example, YAG (yttrium-aluminum-garnet) fluorescent materials that absorb blue light and emit yellow light. The YAG fluorescent materials can be expressed by the following general formula.

(RE₁₋ₓSmₓ)₃(Al_{y}Ga_{1-y})₅O₁₂:Ce

Here, 0≦x≦1, 0≦y≦1, and RE represents at least one kind of element that is selected from the elements Y and Gd.

The resin body 15, for example, is a silicone resin with transparency to blue light and yellow light. The resin body 15 includes the fluorescent materials 14 at about 40-50 wt %, for instance. The resin body 15 covers the semiconductor light-emitting element 11 and the wires 18 and 19.

The resin body 15 has a dome shaped and its size continuously decreases with increased distance from the first and second lead frames 12 and 13. In other words, the size of the upper portion of the resin body 15 is smaller than the size of the lower portion of the resin body 15, which is near the first and second lead frames 12 and 13.

Since the resin body 15 has a dome shape and does not have a side surface that is approximately perpendicular to the first and second lead frames 12 and 13, the resin body 15 is not exposed to the exterior by the transparent resin body 16.

The transparent resin body 16 has a rectangular parallelepiped shape, and its upper surface 16a is approximately parallel with the same plane on which the first and second lead frames 12 and 13 lie. The transparent resin body 16 covers the resin body 15, exposes the lower surfaces 12c and 13c of the first and second lead frames 12 and 13, and covers the first and second lead frames 12 and 13. The transparent resin body 16 may be, for example, a thermosetting epoxy resin or silicone resin.

The transparent resin body 16 is formed to protect the resin body 15 and to improve the handling properties of the semiconductor light-emitting device 10, such as for pickup when the semiconductor light-emitting device 10 is mounted on a substrate.

In the semiconductor light-emitting device 10, directional scattering of the chromaticity is reduced by making the luminous intensity distribution characteristics of the resin body 15 approach the luminous intensity distribution characteristics of the semiconductor light-emitting element 11.

Next, the luminous intensity distribution characteristics of the semiconductor light-emitting device 10 of this embodiment will be explained by comparing with the luminous intensity distribution characteristic of a semiconductor light-emitting device known in the art.

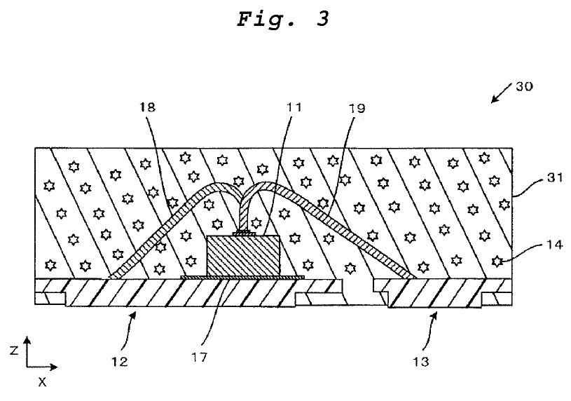

FIG. 3 is a cross sectional diagram showing a semiconductor light-emitting device of a comparative example. As shown in FIG. 3, in a semiconductor light-emitting device 30 of the comparative example, a semiconductor light-emitting element 11 is embedded in a resin body 31 with a rectangular parallelepiped shape containing fluorescent materials 14.

In the semiconductor light-emitting device 30 of the comparative example, the resin body 31 has a rectangular parallelepiped shape, and multiple fluorescent materials 14 are distributed obliquely upwards from the semiconductor light-emitting element 11. As a result, since the probability that blue light emitted obliquely upwards from the semiconductor light-emitting element 11 will make contact with the fluorescent materials is high, it is difficult for the blue light to exit out of the resin body 31.

Therefore, the intensity ratio of the blue light and the yellow light depends upon the viewing direction, as well as chromaticity scattering (color breakup). The chromaticity scattering (color breakup) is a phenomenon in which the whiteness is changed in accordance with the viewing direction when the blue light and the yellow light are mixed.

On the other hand, in the semiconductor light-emitting device 10 of this embodiment, the resin body 15 has a dome shape, and the fluorescent materials 14 are entirely distributed from a view of the semiconductor light-emitting element 11. As a result, the probability that the blue light will be emitted obliquely upward from the semiconductor light-emitting element 11 with the fluorescent materials is lowered, compared with the resin body 31 of the comparative example, the blue light easily exits to the outside of the resin body 15.

Therefore, even if the intensity ratio of the blue light and the yellow light depends upon the viewing direction, its difference is decreased, reducing the chromaticity scattering due to the viewing direction.

In other words, even if there is a difference in the intensity between the blue light and the yellow light, there is no problem as long as the intensity ratio of the blue light and the yellow light is the same. The luminous intensity distribution characteristic of the blue light and the luminous intensity distribution characteristic of the yellow light are made similar, thus being able to reduce the chromaticity scattering due to the direction.

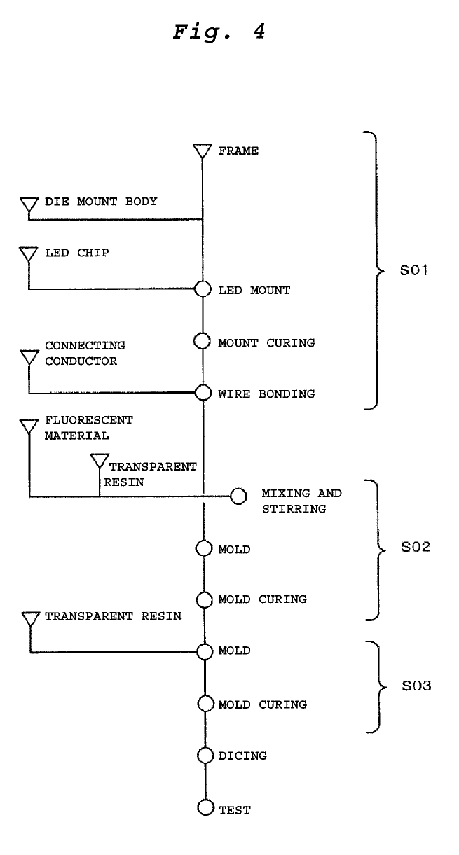

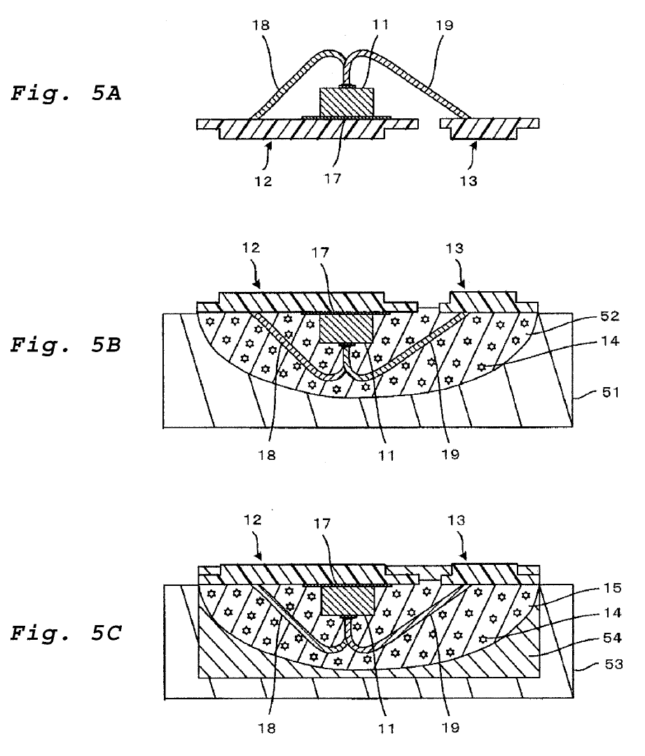

Next, the method for manufacturing the semiconductor light-emitting device 10 will be explained with reference to FIGS. 4 and 5A to 5C. FIG. 4 is a flow chart showing the manufacturing processes of the semiconductor light-emitting device 10; FIGS. 5A to 5C are cross sectional diagrams which sequentially show the main stages of the manufacturing processes of the semiconductor light-emitting device 10.

As shown in FIG. 5A, the lead frames 12 and 13 are prepared. The lead frames 12 and 13 are parts of a lead frame from which the lead frames 12 and 13 are repeatedly formed as one unit in the Y direction.

The semiconductor light-emitting element 11 is mounted on the base part 12a of the lead frame 12 by using the die mount medium 17. The wire 18 is bonded to the first terminal 11a of the semiconductor light-emitting element 11 and the base part 12a of the lead frame 12. The wire 19 is bonded to the second terminal 11b of the semiconductor light-emitting element 11 and the base part 13a of the lead frame 13 (step S01).

As shown in FIG. 5B, for example, a liquid silicone resin 52 containing the fluorescent materials 14 is injected with a dispenser (not shown) into a mold 51 having a dome-shaped, concave part which can surrounds the semiconductor light-emitting element 11. Next, the lead frames 12 and 13 are turned over, and the semiconductor light-emitting element 11 is inserted into the concave part of the mold 51, and the silicone resin 52 is cured at a prescribed temperature. The cured silicone resin 52 is drawn out of the mold 51 (step S02).

Therefore, the dome-shaped resin body 15, which covers the semiconductor light-emitting element 11 and the wires 18 and 19 mounted and bonded to the lead frames 12 and 13 and which includes the fluorescent materials 14, can be obtained.

As shown in FIG. 5C, a dispenser (not shown) is used to inject, for example, a liquid epoxy resin 54 into a mold 53 having a concave part with a rectangular parallelepiped shape, which can house the resin body 15. Next, the lead frames 12 and 13 are turned over, and the resin body 15 is placed in the concave part of the mold 53, and thereafter the epoxy resin 54 is cured at a prescribed temperature. Once cured, the epoxy resin 54 is drawn out of the mold (step S03).

Therefore, the transparent resin body 16 with a rectangular parallelepiped shape, which covers the dome-shaped resin body 15, can be obtained. The transparent resin body 16 has an upper surface 16a that is approximately parallel with the plane on which the lead frames 12 and 13 have been arranged.

As explained above, in the semiconductor light-emitting device 10 of this embodiment, the dome-shaped resin body 15 containing the fluorescent materials 14 is installed on the lead frames 12 and 13 arranged with a separation on the same plane in a manner such that the semiconductor light-emitting element 11 is embedded in the resin body.

As a result, as compared with the rectangular resin body 31 having a rectangular parallelepiped shape and containing the fluorescent materials 14, the intensity of blue light increases from the oblique upper side toward the lower side, and the ratio of yellow light is close to the ratio in the front direction. Therefore, a semiconductor light-emitting device with little scattering of the chromaticity due to the direction can be obtained.

Here, the dome shape of the resin body 15 is not particularly limited but can be appropriately configured in accordance with the luminous intensity distribution characteristics of blue light of the semiconductor light-emitting element so that scattering of the chromaticity due to the direction is improved.

The case in which the first and second terminals 11a and 11b are installed on the upper surface of the semiconductor light-emitting element 11 has been explained, but the surface on which the first and second terminals 11a and 11b are installed is not limited to this upper surface or the particular locations depicted in FIG. 2.

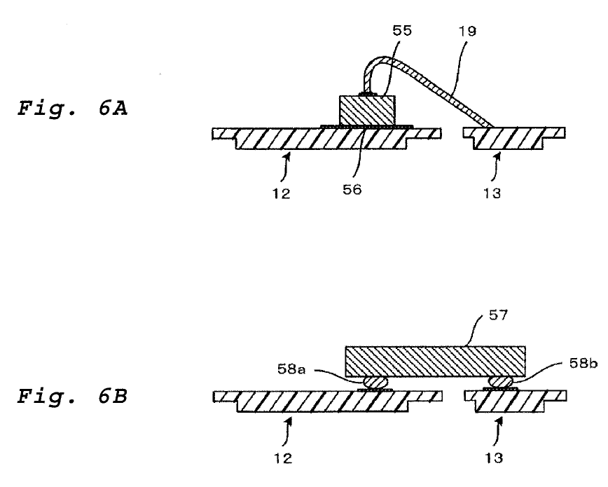

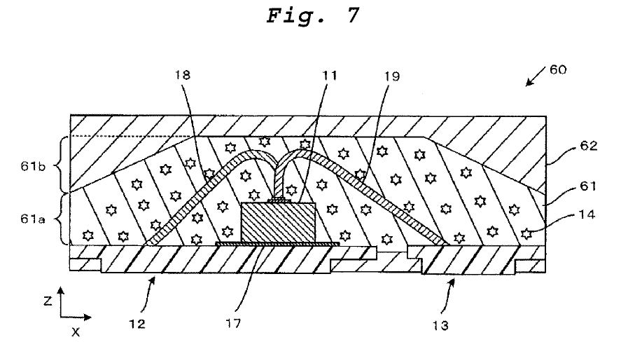

FIGS. 6A and 6B are cross sectional diagrams showing the main parts of another semiconductor light-emitting device. As shown in FIG. 6A, when the semiconductor light-emitting element 55 is a vertical conductive type, a first terminal is installed on the lower surface of the semiconductor light-emitting element 55 and a second terminal is installed on the upper surface of the semiconductor light-emitting element 55. The semiconductor light-emitting element 55 is mounted on the lead frame 12 by a conductive die mount medium 56. The wire 18 is thus not required.

As shown in FIG. 6B, when the semiconductor light-emitting element 57 is a flip chip, bumps 58a and 58b are installed on a surface of the semiconductor light-emitting element 57. The bumps 58a and 58b are thermocompression-bonded to the lead frames 12 and 13, thereby enabling a flip-chip mounting of the semiconductor light-emitting element 57 on the lead frames 12 and 13. The wires 18 and 19 are thus not required.

The case in which the fluorescent materials 14 are YAG fluorescent materials has been explained, but the kinds of fluorescent materials are not limited to that case. For example, SIALON red fluorescent materials or SIALON green fluorescent materials may be used. Blue light, red light, or green light is mixed, thus being able to form a semiconductor light-emitting device that emits light with little chromaticity scattering.

The case in which the resin body has a dome shape has been explained. However, this disclosure is not limited to such a shape. Rather, any shape that lessens directional scattering of the chromaticity may be adopted in accordance with the luminous intensity distribution characteristic of blue light of the semiconductor light-emitting element. For example, a shape in which the lower side has a rectangular parallelepiped shape and the upper surfaces have a quadrangular pyramidic trapezoidal shape may be adopted. A shape in which the lower portion has a first rectangular parallelepiped shape and the upper portion has a second rectangular parallelepiped shape which is smaller than the first rectangular parallelepiped shape may be adopted. A shape in which the area of the upper side of the resin body containing the fluorescent materials 14 is smaller than the area of the lower side may be adopted.

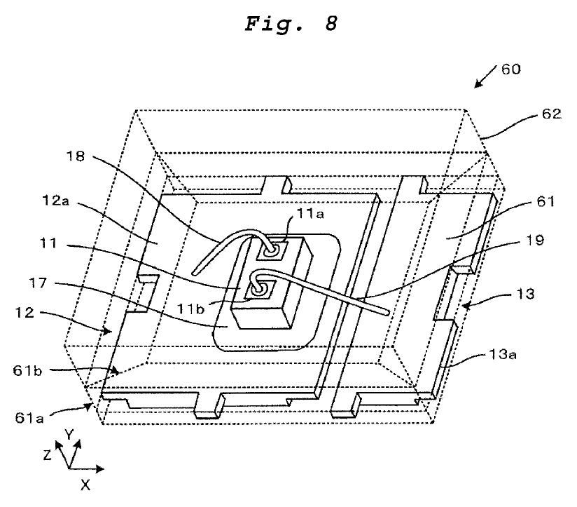

FIGS. 7 and 8 show another semiconductor light-emitting device. FIG. 7 is its cross section and FIG. 8 is its perspective view.

As shown in FIGS. 7 and 8, in another semiconductor light-emitting device 60, the lower part 61a (lower side) of a resin body 61 containing the fluorescent materials 14 has a rectangular parallelepiped shape while its upper part 61b (upper side) has a quadrangular pyramidic trapezoidal shape. The volume of the upper part 61b is less than the volume of the lower part 61a.

The transparent resin body 62 with a rectangular parallelepiped shape exposes the side surface (the side surface of the lower part 61a) of the resin body 61 approximately perpendicular to the lead frames 12 and 13 and covers the resin body 61.

In the resin body 61, the concentration of the fluorescent materials 14 is lowered, compared with the resin body 31 of the comparative example shown in FIG. 3. Therefore, similarly to the resin body 15 of the embodiment shown in FIG. 1, blue light is relatively increased toward the lower part 61a and yellow light is reduced, increasing the ratio of the blue light and the yellow light. In light that is emitted from the lower part of the semiconductor light-emitting device 60, yellowness is reduced. Thus, directional scattering of the chromaticity can be lessened.

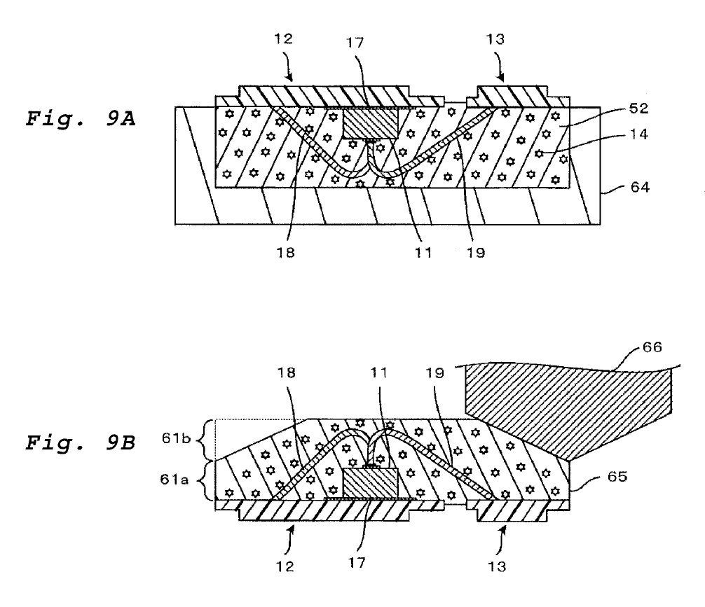

FIGS. 9A and 9B are cross sections showing the main parts of the manufacturing processes of the semiconductor light-emitting device 60 of the embodiment described with respect to FIGS. 7 and 8. As shown in FIG. 9A, for example, a liquid silicone resin 52 containing fluorescent materials 14 is injected with a dispenser (not shown) into a mold 64 having a concave part with a rectangular parallelepiped shape, which can house the semiconductor light-emitting element 11. Next, the lead frames 12 and 13 are turned over, the semiconductor light-emitting element 11 is placed within the mold 64, and the silicone resin 52 therein is cured at a prescribed temperature. The cured silicone resin 52 is drawn out of the mold 64 (step S02).

Therefore, a resin body 65 with a rectangular parallelepiped shape, which covers the semiconductor light-emitting element 11 and the wires 18 and 19 mounted and bonded to the lead frames 12 and 13, and which includes the fluorescent materials 14, can be obtained.

As shown in FIG. 9B, using a blade 66 with a V-shaped cross section, the resin body 65 is half cut along a prescribed dicing line. Therefore, the resin body 65 with a rectangular parallelepiped shape becomes a resin body 61 having a lower part 61a with a rectangular parallelepiped shape and an upper part 61b with a quadrangular pyramidic trapezoidal shape.

Here, the resin body 61 can also be formed by placing the semiconductor light-emitting element 11 in a mold having a concave part with a lower rectangular parallelepiped shaped part and an upper quadrangular pyramidic trapezoidal shaped part, and molding the liquid silicone resin 52 containing the fluorescent materials 14.

The ratio of the height of the lower part 61a and the height of the upper part 61b, and the ratio of the width of the lower part 61a and the width of the upper part 61b, are not restricted by this disclosure, but rather, may be appropriately set so that directional scattering of the chromaticity is lessened.

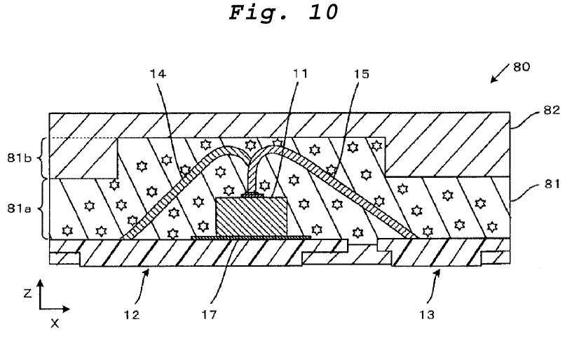

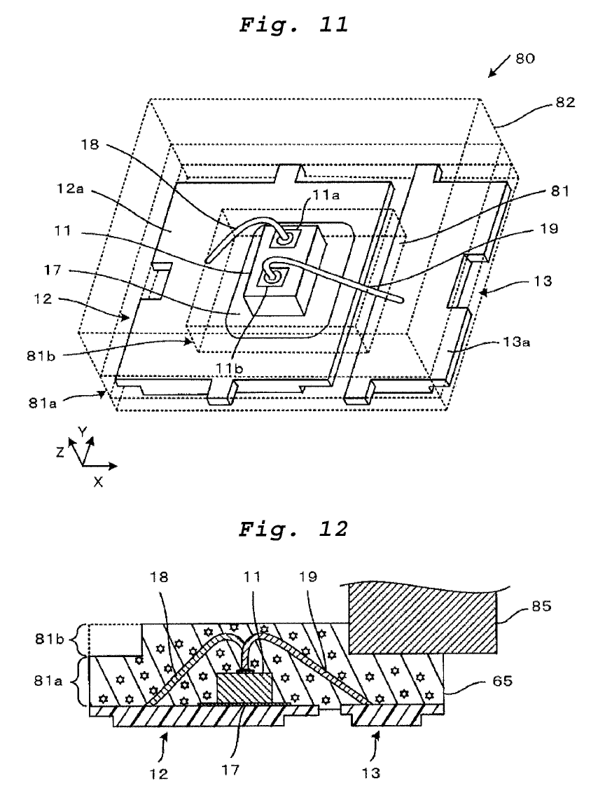

FIG. 10 and FIG. 11 show another semiconductor light-emitting device. FIG. 10 is a cross-section view and FIG. 11 is a perspective view.

As shown in FIGS. 10 and 11, in a semiconductor light-emitting device 80, the lower part 81a (lower side) of a resin body 81 containing fluorescent materials 14 has a first rectangular parallelepiped shape, and its upper part 81b (upper side) has a second rectangular parallelepiped shape smaller in size than the first rectangular parallelepiped shape.

The transparent resin body 82 with a rectangular parallelepiped shape exposes the side surface (the side surface of the lower part 81a) of the resin body 81 approximately perpendicular to the lead frames 12 and 13 and covers the resin body 81.

In the resin body 81, the content of the oblique upward fluorescent materials 14 is lowered, compared with the resin body 31 of the comparative example shown in FIG. 3. Therefore, similarly to the resin body 15 of the embodiment shown in FIG. 1, blue light is relatively increased toward the lower part 81a and yellow light is reduced, increasing the ratio of the blue light to yellow light. In light that is emitted from the lower part of the semiconductor light-emitting device 80, yellowness is reduced. Directional scattering of the chromaticity due to the direction can be lessened.

FIG. 12 is a cross section showing the main parts of the manufacturing processes of the semiconductor light-emitting device 80. As shown in FIG. 12, for example, using a blade 85 with a rectangular cross section, the resin body 65 is half cut along a prescribed dicing line. Therefore, the resin body 65 with a rectangular parallelepiped shape becomes the resin body 81 having the lower part 81a with a first rectangular parallelepiped shape and the upper part 81b with a second rectangular parallelepiped shape smaller than the first rectangular parallelepiped shape.

Here, the resin body 81 can also be formed by placing the semiconductor light-emitting element 11 in a mold having a concave part having a lower part with a first rectangular parallelepiped shape and an upper part with a second rectangular parallelepiped shape smaller than the first rectangular parallelepiped shape, and molding the resin body 81 using liquid silicone resin 52 containing the fluorescent materials 14.

The ratio of the height of the lower part 81a and the height of the upper part 81b, and the ratio of the width of the lower part 81a and the width of the upper part 81b, are not to be limited herein, but rather, can be appropriately set so that scattering of the chromaticity due to the direction is improved.

In addition, the case in which the sides of the first rectangular parallelepiped and the sides of the second rectangular parallelepiped are parallel to each other has been explained, but the sides of the first rectangular parallelepiped and the sides of the second rectangular parallelepiped may be arranged so that they intersect with each other.

While certain embodiments have been described, these embodiments have been presented by way of example only, and are not intended to limit the scope of the invention. Indeed, the novel embodiment described herein may be embodied in a variety of other forms; furthermore, various omissions, substitutions and changes in the form of the embodiments described herein may be made without departing from the spirit of the invention. The accompanying claims and their equivalents are intended to cover such forms or modifications as would fall within the scope and spirit of the invention.

What is claimed is:

1. A semiconductor light-emitting device, comprising:
first and second lead frames arranged with a separation on a common plane;
a semiconductor light-emitting element that is electrically connected to the first and second lead frames; and
a resin body that covers the first and second lead frames and the semiconductor light-emitting element, and includes fluorescent materials that absorb light emitted from the semiconductor light-emitting element and emit light with a wavelength longer than the wavelength of the light absorbed, the resin body having a shape that becomes smaller in cross-section with increasing distance from the common plane.

2. The semiconductor light-emitting device of claim 1, further comprising:
a transparent resin body that has an upper surface approximately parallel with the common plane and a side surface approximately perpendicular to the common plane, and covers the resin body.

3. The semiconductor light-emitting device of claim 2, wherein the transparent resin body covers part of the lower surfaces and part of the end surfaces of the first and second lead frames, and exposes the remaining parts of the lower surfaces and the end surfaces of the first and second lead frames.

4. The semiconductor light-emitting device of claim 1, wherein the shape of the resin body becomes continuously smaller in cross-section with increasing distance from the common plane.

5. The semiconductor light-emitting device of claim 4, wherein
the resin body has a dome shape.

6. The semiconductor light-emitting device of claim 1, wherein
the resin body has a lower portion with a rectangular parallelepiped shape, and an upper portion with a quadrangular pyramidic trapezoidal shape.

7. The semiconductor light-emitting device of claim 1, wherein
the resin body has a lower portion with a first rectangular parallelepiped shape, and an upper portion with a second rectangular parallelepiped shape smaller than the first rectangular parallelepiped shape.

8. The semiconductor light-emitting device of claim 1, wherein the semiconductor light-emitting element has first and second terminals, where the first terminal is electrically connected to the first lead frame and the second terminal is electrically connected to the second lead frame.

9. The semiconductor light-emitting device of claim 8, further comprising one or more wires that electrically connect the semiconductor light-emitting element to the first and second lead frames, the wires being covered by the resin body.

10. The semiconductor light-emitting device of claim 8, further comprising bumps that electrically connect the semiconductor light-emitting element to the first and second lead frames.

11. A semiconductor light-emitting device, comprising:
first and second lead frames;
a semiconductor light-emitting element that is electrically connected to the first lead frame and the second lead frame; and
a dome-shaped resin body that covers the first and second lead frames and the semiconductor light-emitting element, and includes fluorescent materials that absorb light that is emitted from the semiconductor light-emitting element and emit light with a wavelength longer than the wavelength of the light absorbed.

12. The semiconductor light-emitting device of claim 11, wherein the semiconductor light-emitting element is a nitride semiconductor light-emitting element.

13. The semiconductor light-emitting device of claim 11, further comprising:
a transparent resin body with at least five flat and mutually perpendicular sides that covers the resin body.

14. The semiconductor light-emitting device of claim 13, wherein the transparent resin body has a concave section in which the resin body is disposed.

15. The semiconductor light-emitting device of claim 14, wherein the resin body is a silicone resin and the transparent resin body is an epoxy resin.

16. The semiconductor light-emitting device of claim 11, wherein the fluorescent materials are YAG fluorescent materials.

17. A semiconductor light-emitting device, comprising:
first and second lead frames arranged on a common plane;
a semiconductor light-emitting element that is electrically connected to the first lead frame and the second lead frame; and
a non-parallelepiped shaped resin body that covers the first and second lead frames and the semiconductor light-emitting element, and includes fluorescent materials that absorb light that is emitted from the semiconductor light-emitting element and emit light with a wavelength longer than the wavelength of the light absorbed,
wherein at least two optical paths from the semiconductor light-emitting element passing through the resin body, including a first optical path that is perpendicular to the common plane a second optical path that is parallel to the common plane, have substantially the same lengths.

18. The semiconductor light-emitting device of claim 17, further comprising:
a transparent resin body with at least five flat and mutually perpendicular sides that covers the resin body.

19. The semiconductor light-emitting device of claim 18, wherein the transparent resin body has a concave section in which the resin body is disposed.

20. The semiconductor light-emitting device of claim 19, wherein the resin body is a silicone resin and the transparent resin body is an epoxy resin.
